(19) United States
(12) Patent Application Publication
(10) Pub. No.: US 2006/0217023 A1
(43) Pub. Date: Sep. 28, 2006

(54) Apparatus for fabricating electroluminescent display device

(75) Inventors: Chong Hyun Park, Buk-gu (KR); Yoon Heung Tak, Gumi-city (KR)

Correspondence Address: FLESHNER & KIM, LLP, P.O. BOX 221200, CHANTILLY, VA, 20153, US

(73) Assignee: LG Electronics Inc.

(21) Appl. No.: 11/378,294

(22) Filed: Mar. 20, 2006

(30) Foreign Application Priority Data
Mar. 22, 2005 (KR) 10-2005-0023845

(51) Int. Cl. H01J 9/24; H01J 9/00

(52) U.S. Cl. 445/24

(57) ABSTRACT

The apparatus for fabricating organic electroluminescent device which can distribute stress applied to the mask uniformly is disclosed. The apparatus for fabricating an organic electroluminescent device according to the present invention comprises a plurality of grippers disposed at a periphery of a mask for clamping the mask; a plurality of jaws formed on each gripper and contacted with the mask; and power supplying units for supplying power to the grippers to stretch the mask. Each gripper consists of an upper section and a lower section, and at least two jaws each are formed on corresponding surfaces of the upper and lower sections. The jaws are arranged in a line on each gripper or in the zigzag state on each gripper. At this time, the jaws are arranged by equal distance from each other. Also, the jaws can be randomly arranged on the gripper.

### BACKGROUND OF THE INVENTION

1. Field of the Invention

The present invention relates to an apparatus for fabricating an electroluminescent display device, particularly to an apparatus for fabricating an electroluminescent display device capable of distributing stress applied to a mask uniformly to form a precise and reliable pixel.

2. Description of the Related Art

Recently, various kinds of flat display devices having less weight and volume have been developed to substitute the cathode ray tube (CRT) having huge weight and volume. Liquid crystal display device, field emission display device, plasma display panel, and electro-luminescence display device (hereinafter, referred to as “EL” display device) are the examples of such flat display device.

Among these flat display devices, the EL display device is a self light-emitting device in which light is emitted from fluorescent material by re-combining holes with electrons. The EL display device is classified into non-organic EL display device using nor-organic material as fluorescent material, and organic EL display device using organic material as fluorescent material.

Compared with a passive light emitting device requiring an additional light source such as liquid crystal display device, the EL display device is advantageous in that the response time is short to the same level as the cathode ray tube. Also, the EL display device has many advantages such as low-voltage drive, self light-emission, thin film shape, wide view angle, short response time, high contrast, and the like, and so is expected to be next generation display device.

FIG. 1 is a sectional view showing the structure of general organic EL cell for illustrating the light-emitting principle of organic EL display device. The organic EL cell comprises an organic light-emitting layer 110 disposed between an anode 104 and a cathode 112, and the organic light-emitting layer 110 consists of an electron injection layer 10a, an electron transport layer 10b, an light emitting layer 10c, a hole transport layer 10d, and a hole injection layer 10e.

Once power voltage is applied to the anode 104 and the cathode 112, electrons generated from the cathode 112 are transported toward the light emitting layer 10c through the electron injection layer 10a and the electron transport layer 10b. Also, holes generated from the anode 104 are transported toward the light emitting layer 10c through the hole injection layer 10e and the hole transport layer 10d. Accordingly, electrons supplied through the electron transport layer 10b are collided and re-combined with holes supplied through the hole transport layer 10d in the light emitting layer 10c, from which light is emitted. This light is radiated to an exterior through the anode 104 to display an image.

FIG. 2 is a view showing the organic EL display device.

In the organic EL display device shown in FIG. 2, first electrodes 104 (hereinafter, referred to as “anodes”) and second electrodes 112 (hereinafter, referred to as “cathodes”) are formed on the substrate 102 in a crossing direction each other.

The anodes 104 are formed on the substrate 102 by certain distance from each other. On the substrate 102 in which the anodes 104 are formed, an insulating layer (not shown) having a plurality of openings is formed, wherein each opening corresponds to an EL cell area. Walls 108 are formed on the insulating layer to divide organic light emitting layers 110 and cathodes 112 formed thereon. Each wall 108 is formed in the direction perpendicular to the anodes 104, and has an inverse taper structure in which the upper end side is larger than the lower end side. After the walls 108 are formed on the insulating layer, the organic light emitting layers 110 made of organic material and the cathodes 112 are sequentially formed on the entire insulating layer. As shown in FIG. 1, the hole injection layer 10c, the hole transport layer 10d, the light emitting layer 10c, the electron transport layer 10b, and the electron injection layer 10a are sequentially formed to form each organic light emitting layer 110.

Here, red (R) colored light-emitting layer, green (G) colored light-emitting layer and blue (B) colored light-emitting layer are formed on the EL cell areas by using a stretched mask provided in the manufacturing apparatus.

The light emitting layer 10c of the organic EL display device shown in FIG. 1 is formed through thermal deposition and vacuum deposition processes using a grill mask. The grill mask has a plurality of grills formed thereon and corresponding to the light emitting layers to be formed on the substrate. The manufactured grill mask is stretched by a mask clamping/stretching apparatus into a predetermined dimension, and then fixed to a mask frame of the manufacturing apparatus. In the process of forming the light emitting layer, the mask fixed to the mask frame is placed on a surface of the substrate, and so the light emitting layer 10c is formed on the surface of the substrate corresponding to the grill formed on the mask.

A plurality of grippers are mounted to the mask clamping/stretching apparatus. By pulling the grippers in the state that the mask is gripped with the grippers, the mask is stretched. In this process, a stress is applied onto a portion corresponding to each gripper in a periphery of the mask. If the magnitude of stress applied to one portion of the mask differs from that applied to another portion for some reasons, the magnitude of tension force applied to one grill differs from that applied to other grill depending on the position of grill. As a result, the stretching amounts of the grills cannot but differ from each other.

If the stretching amounts of the grills differ from each other, the size (area) of the light emitting layers formed by the grills also become different from each other. Accordingly, each light emitting layer is not formed correctly on a predetermined position, and sizes (areas) of the light emitting areas in the display device are different from each other.

### SUMMARY OF THE INVENTION

The present invention intends to solve the above problem occurred in the course of forming the light emitting layer. Thus, the object of the present invention is to provide an apparatus for fabricating an electroluminescent device which can distribute stress applied to the mask uniformly to form precise and reliable light emitting layers.

For achieving the above object, an apparatus for fabricating an electroluminescent device according to the present invention comprises a plurality of grippers disposed at a periphery of a mask for clamping the mask; a plurality of jaws formed on each gripper and contacted with the mask; and power supplying units for supplying power to the grippers to stretch the mask. Here, each gripper consists of an upper section and a lower section, and at least two jaws each are formed on corresponding surfaces of the upper and lower sections of each gripper.

The jaws are arranged in a line on each gripper or in the zigzag state on each gripper. At this time, the jaws are arranged by equal distance from each other. Also, the jaws can be randomly arranged on the gripper

### BRIEF DESCRIPTION OF THE DRAWINGS

The present invention will be more clearly understood from the detailed description in conjunction with the following drawings.

FIG. 1 is a view illustrating one pixel of a conventional organic electroluminescent display device;

FIG. 2 is a view showing a conventional organic electroluminescent display device;

FIG. 3 is a view showing the apparatus for fabricating an organic electroluminescent display device according to the present invention;

FIG. 4 is a sectional view taken along line I-I in FIG. 3;

FIG. 5 is a schematic view illustrating even distribution of stress caused by a plurality of jaws on the mask shown in FIG. 4; and

FIG. 6 and FIG. 7 are views showing various arrangement states of the jaws.

### DETAILED DESCRIPTON OF THE INVENTION

Hereinafter, preferred embodiments of the present invention will be described in detail with reference to those accompanying drawings.

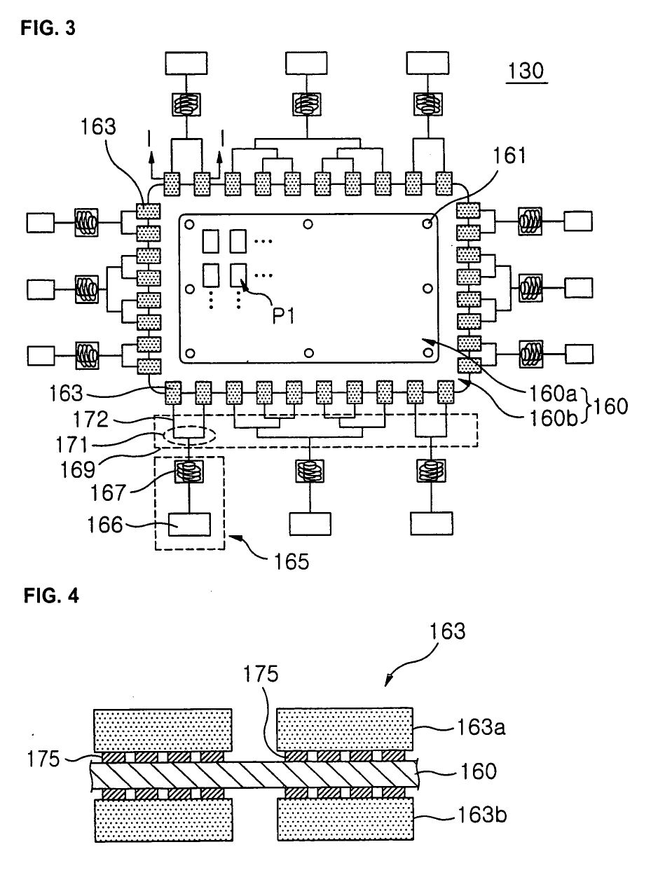

FIG. 3 is a view showing a portion of the apparatus for fabricating an organic EL display device, that is, the mask clamping/stretching apparatus, according to the present invention.

The mask clamping/stretching apparatus 130 shown in FIG. 3 comprises grippers 163 disposed at long sides and short sides of a mask 160 to grip the mask; power supplying units 165 for supplying the power to enable the mask 160 to be stretched; and power transmission units 169 installed for transmitting the power supplied from the power supplying units 165 to the grippers 163. Such mask clamping/stretching apparatus 130 is supported by a clamp holder (not shown).

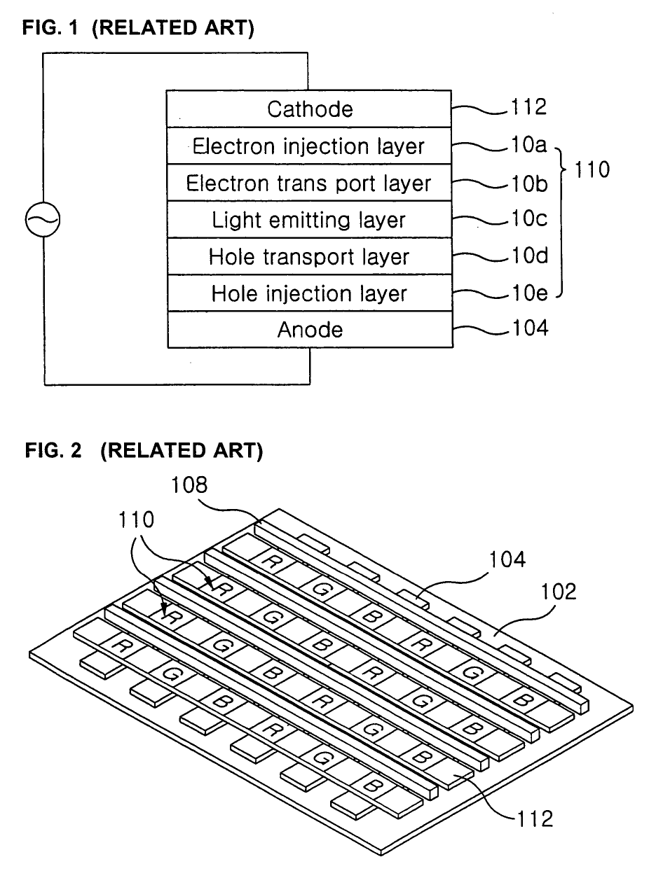

The mask 160 is a grill mask used for forming the R (red), G (green) and B (blue) light emitting layer 10c (in FIG. 1) of the organic EL display device, and is divided into an effective area 160a and a non-effective area 160b except the effective area 160a.

A plurality of array areas P1 are formed on the effective area 160a, and the substrate (not shown) is selectively exposed through the array areas P1 to form the light emitting layers 10c of R (red), G (green), and B (blue) pixels. Also, a plurality of points 161 are formed on an outer periphery of the effective area 160a to provide bases when the mask 160 is stretched. That is, a user decides a stretching limit on the basis of the points 161 marked on the mask 160, and then the mask 160 is stretched by a force corresponding to the stretching limit. The non-effective area 160b is a periphery area of the mask 160 except the effective area 160a, and the grippers 163 grip the non-effective area 160b so that the tension force is applied first to the non-effective area 160b when the mask is stretched.

For example, about ten (10) grippers 163 (gripper group) are disposed at each long side of the mask 160, and about eight (8) grippers (gripper group) are disposed at each short side of the mask. Also, an adjusting screw is mounted to each gripper 163 for adjusting the frictional resistance of the gripper 163.

As shown in FIG. 3, three power supplying units 165 are disposed at each side of the mask 160, and each of power supplying units 165 consists of a motor 166 coupled with the power transmission unit 169, and a ball screw box 167 coupled with the motor 166 for converting a rotational motion of the motor 166 into a linear motion.

Each power transmission unit 169 comprises connecting levers 171 coupled to the ball screw box 167 of the power supplying unit 165 and connecting pins 172 coupled to the connecting levers 171. Each gripper 163 is coupled with each connecting pin 172.

FIG. 4 is a sectional view taken along line I-I in FIG. 3. Each gripper 163 consists of an upper section 163a and a lower section 163b facing the upper section.

Two (2) or more jaws 175 each are formed on inside surfaces of the upper section 163a and the lower section 163b. Each jaw 175 is placed between the upper section 163a /the lower section 163b and the mask 160 to transmit the power transmitted to the gripper 163 to the mask 160. Since a plurality of jaws 175 are disposed on each gripper 163, and each jaw 175 has a relatively small size, it is possible to prevent the stress from being concentrated on a certain area of the mask 160.

Below, the function of each jaw 175 is described in detail.

As shown in FIG. 4, four (4) of jaws 175 are disposed on each of the upper and lower sections 163a and 163b, and each jaw 175 has a relatively small size. A plurality of jaws 175 are contacted with the mask 160 through a limited area, and so it is possible to prevent the stress from being concentrated on a certain area of the mask 160.

That is, as shown in FIG. 4, a force applied to the mask 160 through each gripper 163 is divided into four equal parts, and so the distributed force is applied to an area of the mask 160 corresponding to each jaw 175.

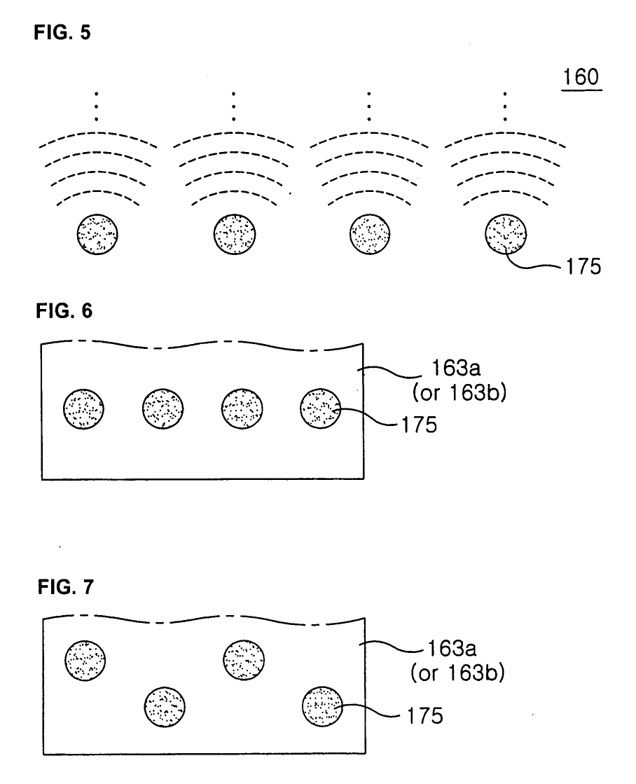

FIG. 5 is a schematic view illustrating even distribution of stress caused by a plurality of jaws on the mask shown in FIG. 4.

As shown in FIG. 5, the stress is uniformly distributed on the entire area of the mask 160, and so an uneven distortion of the mask 160, that is, uneven distortion of the grills formed on the mask 160, is minimized. Consequently, a uniform and reliable organic light emitting layer can be formed through the mask 160.

FIG. 6 and FIG. 7 are views showing various arrangement states of the jaws.

Here, four (4) or more jaws 175 can be arranged in a line on the gripper 163 as shown in FIG. 6 or in the zigzag state on the gripper as shown in FIG. 7. Also, the jaws 175 can be randomly arranged on the gripper 163. Preferably, the jaws 175 formed on each griper 163 are arranged to have equal distance from each other.

The mask clamping/stretching apparatus 130 having the above structure is operated as follows.

First, after the mask 160 is loaded on a certain system, the mask is arranged at an area where the grippers 163 are placed, by a vertical movement.

Thereinafter, the grippers 163 are moved forward to clamp the mask 160, and the motors 166 are driven. A rotational motion of each motor 166 is converted into a linear motion through each ball screw box 167, and then transmitted to the corresponding power transmission unit 169.

At this time, once each power transmission unit 169 to which the power of the motors 166 is transmitted is moved backward, the grippers 163 are also moved backward. Accordingly, the mask 160 contacting with the jaws 175 of each gripper 163 is stretched outward by the gripper 163.

Then, once the mask 160 is stretched and expanded to a designed size, a mask frame (not shown) is disposed below the mask 160, and the mask 160 is then fixed to the mask frame by laser welding. The mask 160 fixed to the mask frame is used in the process of forming the light emitting layer. That is, the mask frame to which the mask 160 is fixed is placed below the substrate, and organic material vapor is passed selectively through the grills formed on the mask 160, and reaches a predetermined light emitting area of the substrate. Accordingly, the organic light emitting layer pattern corresponding to the grills of the mask 160 is formed on the substrate.

In the apparatus for fabricating an organic electroluminescent display device, as described above, four (4) or more pairs of jaws are disposed on each gripper used for clamping the mask. Therefore, it is possible to prevent the stress from being concentrated on a specific area of the mask and distribute the stress uniformly, and so the mask can be stretched uniformly and accurately. Consequently, the light emitting layer can be formed precisely on a predetermined area of the substrate by using such mask to enhance reliability of the organic electroluminescent display device.

The preferred embodiments of the present invention have been described for illustrative purposes, and those skilled in the art will appreciate that various modifications, additions, and substitutions are possible, without departing from the scope and spirit of the present invention as disclosed in the accompanying claims.

What is claimed is:

1. An apparatus for fabricating an electroluminescent display device, comprising a plurality of grippers (gripper group) disposed at a periphery of a mask for clamping the mask;
a plurality of jaws formed on each gripper and contacted with the mask; and
power supplying units for supplying power to the grippers to stretch the mask,
wherein said each gripper consists of an upper section and a lower section, and at least two jaws each are formed on corresponding surfaces of the upper and lower sections.

2. The apparatus for fabricating an electroluminescent display device according to claim 1, wherein the mask has a plurality of grills, and is used for fabricating an organic electroluminescent display device.

3. The apparatus for fabricating an electroluminescent display device according to claim 2, wherein the grills formed of the mask correspond to light emitting areas of a substrate to form light emitting layers of R (red), G (green) and B (Blue) pixels of the organic electroluminescent display device.

4. The apparatus for fabricating an electroluminescent display device according to claim 1, further comprising power transmitting units, each being placed between the gripper group arranged on each side of the mask and corresponding power supplying unit, to enable the grippers to be moved linearly.

5. The apparatus for fabricating an electroluminescent display device according to claim 1, wherein the jaws are arranged in a line on each gripper.

6. The apparatus for fabricating an electroluminescent display device according to claim 5, wherein the jaws are arranged by equal distance from each other.

7. The apparatus for fabricating an electroluminescent display device according to claim 1, wherein the jaws are arranged in the zigzag state on each gripper.

8. The apparatus for fabricating an electroluminescent display device according to claim 7, wherein the jaws are arranged on the gripper by equal distance from each other.

9. The apparatus for fabricating an electroluminescent display device according to claim 1, wherein the jaws are randomly arranged on the gripper

10. An apparatus for clamping and stretching a mask having grills formed thereon and corresponding to light emitting areas of a substrate to form light emitting layers of R (red), G (green) and B (Blue) pixels of the organic electroluminescent display device, comprising
a plurality of grippers (gripper group) disposed at a periphery of the mask for clamping the mask;
a plurality of jaws formed on each gripper and contacted with the mask;
power supplying units for supplying power to the grippers to stretch the mask; and
power transmitting units, each being placed between the gripper group arranged on each side of the mask and corresponding power supplying unit to enable the grippers to be moved linearly,
wherein said each gripper consists of an upper section and a lower section, and at least two jaws each are formed on corresponding surfaces of the upper and lower sections.

11. The apparatus for fabricating an electroluminescent display device according to claim 10, wherein the jaws are arranged in a line on each gripper.

12. The apparatus for fabricating an electroluminescent display device according to claim 11, wherein the jaws are arranged by equal distance from each other.

13. The apparatus for fabricating an electroluminescent display device according to claim 10, wherein the jaws are arranged in the zigzag state on each gripper.

14. The apparatus for fabricating an electroluminescent display device according to claim 13, wherein the jaws are arranged on the gripper by equal distance from each other.

15. The apparatus for fabricating an electroluminescent display device according to claim 10, wherein the jaws are randomly arranged on the gripper.
